(19) United States
(12) Patent Application Publication
(10) Pub. No.: US 2025/0158254 A1
(43) Pub. Date: May 15, 2025

(54) BATTERY MONITORING SYSTEMS WITH DIRECT ELECTRICAL CONNECTION FOR CAPACITANCE MEASUREMENT IN BATTERY CELLS

(71) Applicant: GM GLOBAL TECHNOLOGY OPERATIONS LLC, Detroit, MI (US)

(72) Inventors: Michael P. BALOGH, Novi, MI (US); Nicholas Paul William PIECZONKA, Windsor (CA); Ratandeep Singh KUKREJA, Auburn Hills, MI (US)

(21) Appl. No.: 18/510,104

(22) Filed: Nov. 15, 2023

(51) Int. Cl. H01M 50/569; G01R 27/26; H01M 50/105; H01M 50/119; H01M 50/121; H01M 50/129; H01M 50/553; H01M 50/562; H01M 50/564; H01M 50/567

(52) U.S. Cl. CPC H01M 50/569; G01R 27/2605; H01M 50/105; H01M 50/119; H01M 50/121; H01M 50/129; H01M 50/553; H01M 50/562; H01M 50/564; H01M 50/567

(57) ABSTRACT

A battery cell includes a battery cell enclosure having an inner layer made of an electrically conductive material and an outer layer made of an electrically insulative material. A portion of the inner layer is exposed. The battery cell further includes first battery terminals arranged in the battery cell enclosure, second battery terminals arranged in the battery cell enclosure, electrolyte located between the first battery terminals and the second battery terminals, and a conductive portion arranged adjacent to the outer layer and directly connected to the exposed portion of the inner layer. Other example battery cells, battery systems with capacitance measurement modules, and methods for measuring capacitance values associated with battery cells are also disclosed.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates to battery cells and battery systems, and more particularly to battery monitoring systems with direct electrical connection for capacitance measurement in battery cells of electrically powered systems (e.g., electric vehicles, etc.).

Electric vehicles (EVs) such as battery electric vehicles (BEVs), hybrid vehicles, and/or fuel cell vehicles include one or more electric machines and a battery system including one or more battery cells. The battery cells can be arranged in battery modules including two or more battery cells and/or in battery packs including two or more battery modules. A power control system is used to control charging and/or discharging of the battery system during charging from a utility, regenerative braking and/or acceleration during driving.

A battery management system (BMS) monitors various parameters of the battery system and controls the operation of the battery system. The battery cells include solid or liquid electrolyte arranged between an anode and a cathode of the battery cell. Over the lifetime of the battery, performance of the battery may decrease due to an interconnected combination of electrolyte dry out, chemistry changes of the solid or liquid electrolyte, loss of active lithium inventory and/or changes in the active materials in the battery cells. In some cases, the BMS may detect these conditions.

### SUMMARY

A battery cell includes a battery cell enclosure having an inner layer made of an electrically conductive material and an outer layer made of an electrically insulative material. A portion of the inner layer is exposed. The battery cell further includes first battery terminals arranged in the battery cell enclosure, second battery terminals arranged in the battery cell enclosure, electrolyte located between the first battery terminals and the second battery terminals, and a conductive portion arranged adjacent to the outer layer and directly connected to the exposed portion of the inner layer.

In other features, the conductive portion is directly connected to the exposed portion of the inner layer via an adhesive material.

In other features, the adhesive material is a pressure sensitive adhesive.

In other features, the adhesive material is a conductive paint.

In other features, the conductive portion is directly connected to the exposed portion of the inner layer via at least one metallic plate clamped to the conductive portion.

In other features, the conductive portion includes a metal foil layer.

In other features, the conductive portion is made of copper or aluminum.

In other features, the electrically insulative material of the outer layer is a polymer material.

In other features, the exposed portion of the inner layer is an edge portion of the battery cell enclosure.

In other features, the battery cell comprises a pouch-type battery cell and the battery cell enclosure comprises a battery pouch.

In other features, the battery cell enclosure includes an interior layer made of an electrically insulative material, and the inner layer includes a metal foil layer laminated between the interior layer and the outer layer.

In other features, the electrically insulative material of the interior layer is a polymer material.

A battery system includes at least one pouch-type battery cell and a capacitance measurement module. The pouch-type battery cell includes a battery pouch having an inner layer made of an electrically conductive material and an outer layer made of an electrically insulative material. A portion of the inner layer is exposed. The pouch-type battery cell further includes first battery terminals arranged in the battery pouch, second battery terminals arranged in the battery pouch, electrolyte located between the first battery terminals and the second battery terminals, and a conductive portion arranged adjacent to the outer layer and directly connected to the exposed portion of the inner layer. The capacitance measurement module is configured to measure capacitance values between the conductive portion of the at least one pouch-type battery cell and at least one of the first battery terminals and the second battery terminals of the at least one pouch-type battery cell.

In other features, the conductive portion is directly connected to the exposed portion of the inner layer via an adhesive material.

In other features, the conductive portion is directly connected to the exposed portion of the inner layer via at least one metallic plate clamped to the conductive portion.

In other features, the conductive portion includes a metal foil layer, and the electrically insulative material of the outer layer is a polymer material.

In other features, the exposed portion of the inner layer is an edge portion of the battery pouch.

In other features, the battery pouch includes an interior layer made of an electrically insulative material, and the inner layer includes a metal foil layer laminated between the interior layer and the outer layer.

In other features, the electrically insulative material of the interior layer is a polymer material.

A method for measuring capacitance values associated with a battery cell is disclosed. The battery cell includes a battery cell enclosure having an inner layer made of an electrically conductive material and an outer layer made of an electrically insulative material, first battery terminals arranged in the battery cell enclosure, second battery terminals arranged in the battery cell enclosure, and electrolyte located between the first battery terminals and the second battery terminals. The method includes exposing a portion of the inner layer of the battery cell enclosure, directly connecting a conductive portion to the exposed portion of the inner layer, and connecting a capacitance measurement module to the conductive portion and the at least one of the first battery terminals and the second battery terminals of the battery cell to measure capacitance values between the conductive portion and the at least one of the first battery terminals and the second battery terminals.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a side cross-sectional view of a battery cell with a conductive portion directly connected to an electrically conductive layer of a battery cell pouch via an adhesive material, according to the present disclosure;

FIG. 2 is a side cross-sectional view of a battery cell with a conductive portion directly connected to an electrically conductive layer of a battery cell pouch via metallic plates, according to the present disclosure;

FIG. 3 is a functional block diagram side of a battery system with the battery cell of FIG. 1 and a capacitance measurement module for monitoring capacitance measurements in of battery cell, according to the present disclosure;

FIG. 4 is a functional block diagram side of a battery management system with a capacitive measurement module according to the present disclosure;

FIG. 5 is a flowchart of an example method for measuring capacitance values associated with a battery cell having a conductive portion directly connected to an electrically conductive layer of a battery cell pouch, according to the present disclosure;

FIG. 6 is a graph illustrating a comparison between measured capacitances with a conductive portion directly connected to an electrically conductive layer of a battery cell pouch and with a conductive portion capacitively coupled to an electrically conductive layer of a battery cell pouch, according to the present disclosure; and

FIGS. 7-10 are graphs illustrating measured capacitance as a function of various different battery parameters over frequency, according to the present disclosure.

In the drawings, reference numbers may be reused to identify similar and/or identical elements.

### DETAILED DESCRIPTION

A battery management system (BMS) monitors various parameters of the battery system and controls the operation of the battery system. Over the lifetime of a battery, performance of the battery may decrease due to an interconnected combination of electrolyte dry out, chemistry changes of the solid or liquid electrolyte, loss of active lithium inventory and/or changes in the active materials in the battery cells. In conventional systems, the BMS may detect these conditions based on capacitance measurements associated with the battery (e.g., one or more battery cells). Specifically, in the conventional BMS, a conductive material (e.g., a metal foil or a conductive plate) is placed on an external surface of a battery cell pouch. In doing so, the external conductive material creates a capacitive coupling with a conductive foil in the battery cell pouch. Then, based on this capacitive coupling and another capacitive coupling between the conductive foil in the battery cell pouch and electrodes in the battery cell, capacitance measurements of the battery cell can be calculated. However, such capacitive couplings often cause imprecise and inaccurate capacitance measurements.

The systems and methods herein leverage a direct electrical connection between an external conductive material and a conductive foil in a battery cell pouch or enclosure for capacitance measurements in a battery cell. In doing so, the systems and methods herein eliminate a capacitive coupling relied on by conventional systems. As a result of the direct electrical connection, the sensitivity and accuracy of capacitance measurements are increased as compared to capacitance measurements achieved with conventional systems. Additionally, with the elimination of the capacitive coupling used to make these measurements, the systems and methods herein simplify and reduce the cost of capacitive measurements for pouch cell battery applications. In various embodiments, the systems and methods can be used for battery quality control, battery state of health monitoring and early detection of thermal runaway.

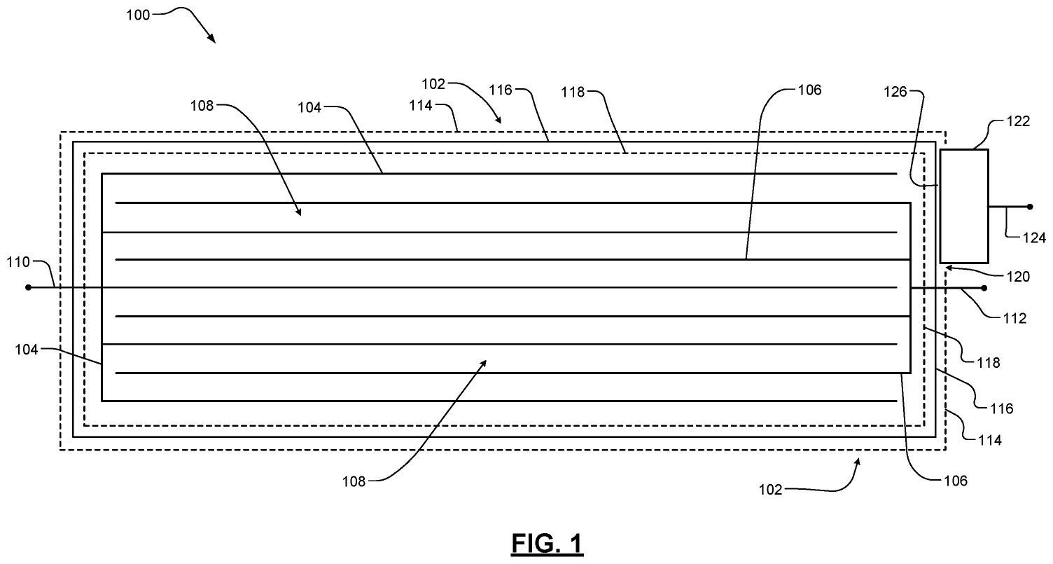

Referring now to FIG. 1, a battery cell 100 generally includes a battery cell enclosure 102, battery terminals 104, 106, and electrolyte 108 located between the battery terminals 104, 106. In such examples, the electrolyte 108 may be solid electrolyte or liquid electrolyte. In various embodiments, the battery cell 100 may be a pouch-type battery cell (e.g., a Li-ion pouch-type battery cell) and the battery cell enclosure 102 may be a pouch, although other types of battery cells and/or battery cell enclosures can be used.

In various embodiments, the battery cell 100 of FIG. 1 and/or any other battery cell or system herein may be employable in vehicle applications. For example, the battery cell 100 may be employed in any suitable vehicle, such as an electric vehicle (e.g., a pure electric vehicle, a plug-in hybrid electric vehicle, etc.), etc. Additionally, the battery cell 100 may be applicable to an autonomous vehicle, a semi-autonomous vehicle, etc. In other examples, the battery cell 100 may be implemented with suitable non-vehicle applications relying on one or more battery cells.

With continued reference to FIG. 1, the battery terminals (e.g., electrodes) 104, 106 are generally arranged in the battery cell enclosure 102. In such examples, the terminals 104 are attached to cathodes or anodes of the battery cell 100 and the terminals 106 are attached to the anodes or cathodes of the battery cell 100. In the example of FIG. 1, the battery terminals 104, 106 are electrically connected to (or form) leads (or tabs) 110, 112, respectively.

In the example of FIG. 1, the battery cell enclosure 102 includes multiple layers of material for sealing the battery terminals 104, 106 and the electrolyte 108 therein. For example, in FIG. 1, the battery cell enclosure (e.g., a pouch) 102 includes an outer layer 114, an inner (or middle) layer 116, and an interior layer 118. In such examples, the interior layer 118 is generally the inner most layer and the outer layer 114 is generally the outer most (e.g., exterior) layer of the battery cell enclosure 102. With this arrangement, the battery terminals 104, 106 may be considered generally adjacent to the interior layer 118 and in some cases the inner layer 116. In various embodiments, the multiple layers may be laminated together such that the inner layer 116 is laminated between the interior layer 118 and the outer layer 114. While the example battery cell 100 of FIG. 1 includes the battery cell enclosure 102 with three layers, it should be appreciated that more or less layers may be employed if desired.

The multiple layers of the battery cell enclosure 102 may include different materials. For example, in FIG. 1, the outer layer 114 and the interior layer 118 may be made of the same or different electrically insulative material. In contrast, the inner layer 116 may be made of an electrically conductive material. For instance, the electrically insulative material may be a non-metallic material, such as a polymer material. Additionally, the electrically conductive material may be a metallic material, such as a metal foil. More specifically, the electrically conductive material may be aluminum, copper, etc. and/or alloys thereof. In various embodiments, the materials of the layers in the battery cell enclosure 102 may be such that the battery cell enclosure 102 is generally flexible.

In various embodiments, the battery cell enclosure 102 includes at least one exposed region. For example, and as shown in FIG. 1, the battery cell enclosure 102 has an exposed region 120. With this configuration, at least a portion of the inner, electrically conductive, layer 116 may be exposed. The exposed region 120 may be created in any suitable manner, such as by cutting the battery cell enclosure 102, by piercing or removing a portion of the outer layer 114 by chemical or mechanical means (e.g., scrapping), etc. For example, when the battery cell enclosure 102 is cut for receiving the interior battery cell components, a portion of the inner layer 116 may be exposed.

The exposed region 120 (or portion) may be at any suitable location along the battery cell enclosure 102. For example, when the exposed portion is formed in the cutting process, the exposed portion may be along an edge portion (or surface) of the battery cell enclosure 102, as shown in FIG. 1. In other examples, the exposed portion may be along a side surface (e.g., a top side, a bottom side, etc.) of the battery cell enclosure 102 if desired. Additionally, in some examples, the exposed portion may extend along only a part of the edge surface (e.g., as shown in FIG. 1) or side surface. Alternatively, the exposed portion may extend along the entire edge surface if desired.

In the example of FIG. 1, the battery cell 100 further includes a conductive portion 122 directly connected to the exposed portion of the inner layer 116. For example, and similar to the inner layer 116, the conductive portion 122 may be made of an electrically conductive material, such as a metallic material. More specifically, the electrically conductive material may be aluminum, copper, etc. and/or alloys thereof. In such examples, the conductive portion 122 may be generally arranged adjacent to the outer layer 114 of the battery cell enclosure 102 and electrically connected to (or form) a lead (or a tab) 124.

In various embodiments, the conductive portion 122 may be a metal foil generally wrapped around at least the exposed portion of the inner layer 116. For example, the conductive portion 122 may extend along a portion of the edge portion/surface and onto the top side and/or the bottom side of the battery cell 100. In other examples, the conductive portion 122 may extend only along a portion of the edge portion/surface.

The conductive portion 122 may be directly connected to the exposed portion of the inner layer 116 in any suitable manner. For example, in FIG. 1, the conductive portion 122 is directly connected to the exposed portion of the inner layer 116 via an adhesive material 126. In such examples, the adhesive material 126 may be any suitable electrically conductive adhesive, such as a pressure sensitive adhesive, a conductive paint, etc. With this arrangement, the conductive portion 122 may be temporarily connected to the exposed portion of the inner layer 116 if desired.

In other examples, the conductive portion 122 may be directly connected to the exposed portion of the inner layer 116 in a more permanent and robust manner. For instance, the conductive portion 122 may directly contact the exposed portion of the inner layer 116 via one or more metallic plates clamped to the conductive portion 122.

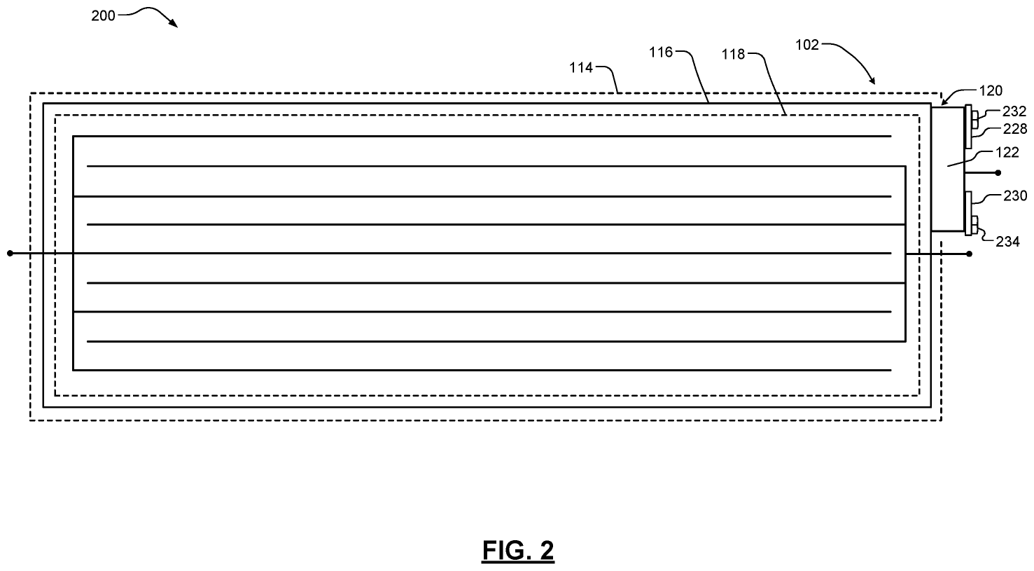

For example, FIG. 2 depicts a battery cell 200 substantially similar to the battery cell 100 of FIG. 1, but with metallic plates for securing the conductive portion 122 to the battery cell 200. More specifically, the battery cell 200 includes the battery cell enclosure 102 with the outer layer 114, the inner layer 116, and the interior layer 118 of FIG. 1, and the conductive portion 122 of FIG. 1 directly connected to the exposed portion of the inner layer 116. However, in the example of FIG. 2, the conductive portion 122 is in direct contact with the exposed portion of the inner layer 116 and secured thereon with two metallic plates 228, 230 clamped to the conductive portion 122. In such examples, the metallic plates 228, 230 may be clamped (or otherwise secured) with one or more fasteners, such as bolts, screws, clamps, etc. In the example of FIG. 2, bolts 232, 234 are employed.

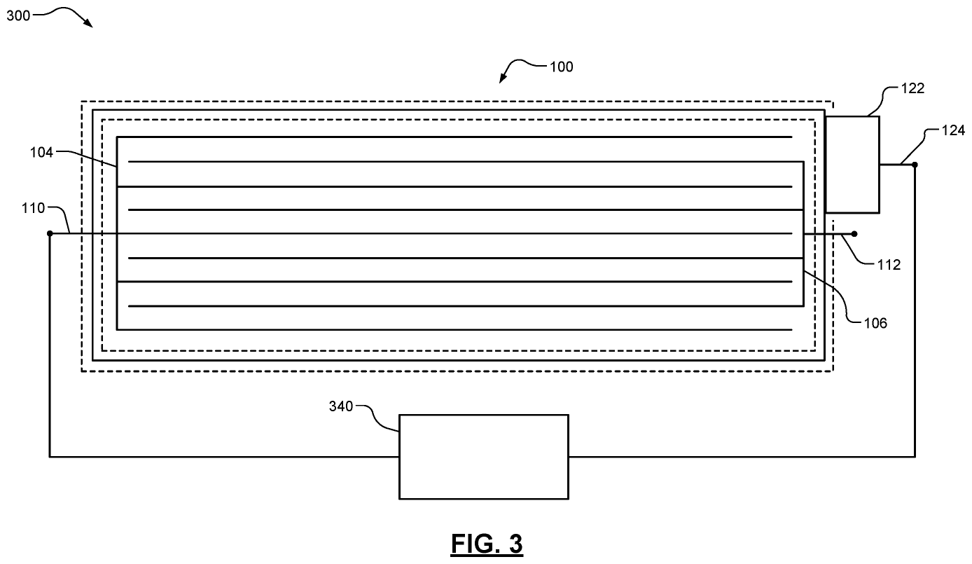

FIG. 3 depicts a battery system 300 for monitoring capacitance measurements in battery cells having direct electrical connections, as explained herein. For example, the battery system 300 includes the pouch-type battery cell 100 of FIG. 1 including the pouch with multiple layers, and a capacitance measurement module (e.g., a controller) 340. While the battery system 300 of FIG. 3 is shown as including only one battery cell 100, it should be appreciated that the battery system 300 or other systems herein may include the battery cell 200 of FIG. 2, multiple battery cells (e.g., battery cells similar to the battery cell 100 and/or the battery cell 200, etc.) if desired.

As shown, the capacitance measurement module 340 is connected to the conductive portion 122 via the lead 124 and the battery terminals 104 via the lead 110. In other examples, the capacitance measurement module 340 may be connected to the conductive portion 122 and the battery terminals 106 via the lead 112 if desired. In such examples, the capacitance measurement module 340 may measure one or more capacitance values between the conductive portion 122 of the pouch-type battery cell 100 and the battery terminals 104 (or the battery terminals 106) of the pouch-type battery cell 100. The measured capacitance value(s) may be employed in diagnostic scenarios as further explained below.

In such examples, the sensitivity and accuracy of capacitance measurements associated with the battery cell 100 of FIG. 3 are increased as compared to capacitance measurements achieved with conventional systems. For example, and as explained above, in conventional systems, a conductive material (e.g., a metal foil or a conductive plate) is placed on an external surface of a battery cell pouch to create a capacitive coupling between the conductive material and a conductive foil in the battery cell pouch. Then, based on this capacitive coupling and another capacitive coupling between the conductive foil in the battery cell pouch and electrodes in the battery cell, capacitance measurements of the battery cell can be calculated. Such calculations may be determined according to equations (1)-(2) below. In equations (1)-(2), C_{measured} is the measured capacitance (e.g., measured with a capacitance measurement module), Cₚₗₐₜₑ is capacitance between the external conductive material and the conductive foil in the battery cell pouch, and C_{cell} is the capacitance between the conductive foil in the battery cell pouch and electrodes in the battery cell. In equation (2), ε₀ is the permittivity of the dielectric material (e.g., an electric constant), A is the area of a parallel plate (e.g., the conductive foil, the electrodes, etc.), d is the distance between the two conductive plates (e.g., between the conductive foil and the electrodes), and K is a dielectric constant of the dielectric material between plates.

$$\frac{1}{{c}_{measured}} = \frac{1}{{c}_{plate}} + \frac{1}{{c}_{cell}} \qquad Equation ( 1 )$$

$${C}_{cell} = \frac{1}{( \frac{1}{{c}_{measured}} - \frac{1}{{C}_{plate}} )} = \frac{K {ε}_{0} A}{d} \qquad Equation ( 2 )$$

However, when the conductive portion 122 of FIGS. 1-2 is directly connected to the exposed portion of the inner layer 116 as explained herein, the capacitance determination of the battery cell may be greatly simplified. In such examples, the capacitive coupling between the conductive material and the conductive foil in the battery cell pouch is eliminated. As such, the measured capacitance (C_{measured}) becomes equal to the battery cell capacitance (C_{cell}), as shown in equation (3) below.

$${C}_{mea sured} = {C}_{cell} = \frac{K {ε}_{0} A}{d} \qquad Equation ( 3 )$$

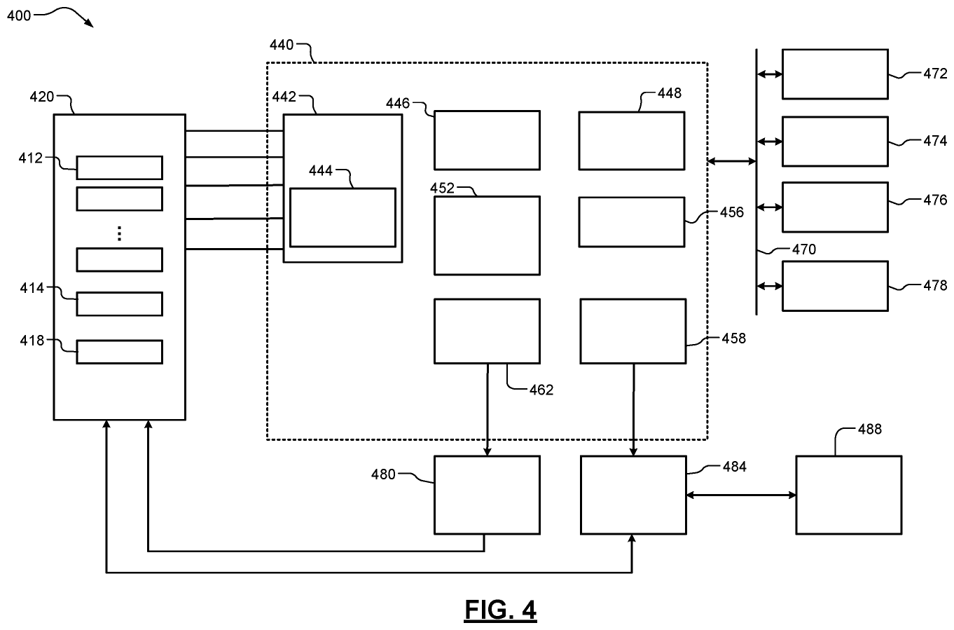

FIG. 4 depicts another battery system 400 for monitoring capacitance measurements in battery cells in an electric vehicle. For example, the battery system 400 includes a battery module 420 including battery cells 412, one or more sensors 414 (such as voltage, current, temperature, etc.), and a module controller 418. In such examples, the battery cells 412 may include one or more of the battery cells 100, 200 of FIGS. 1-2. The module controller 418 may be used to control module level sensing and/or functionality.

A battery management system 440 includes a measurement module 442 that coordinates measurement of values from the battery cell, module and/or pack level. Examples of values include temperatures T₁, T₂, . . . , voltages V₁, V₂, . . . , currents i₁, i₂, . . . , reference voltages V_{ref1}, V_{ref2}, . . . , etc. The measurement module 442 includes a capacitance measurement module 444 that measures one or more capacitance values C₁, C₂, . . . for each of the battery cells and/or performs other calculations described herein.

A state of health (SOH) module 446 calculates the SOH of the battery cells, modules, and/or packs. A scheduling and history module 448 schedules testing of the battery cells at predetermined periods (e.g., operating time, cycles, etc.), in response to predetermined events and/or in response to other factors and stores historical data. A state of change (SOC)/capacity estimation module 452 determines the SOC of the battery cells, modules and/or packs. Calibration data storage 456 stores thresholds, parameters and/or other data related to calibration of the battery system. A thermal management module 462 communicates with a temperature controller 480 to control a temperature of the battery system such as by adjusting coolant flow, airflow and/or other parameters. A power control module 458 controls a power inverter 484 connecting the battery system to one or more loads 488 in a vehicle. The battery management system 440 communicates via a vehicle data bus 470 with a propulsion controller 472, one or more other vehicle controllers 474, a telematics controller 476, and/or a user interface 478.

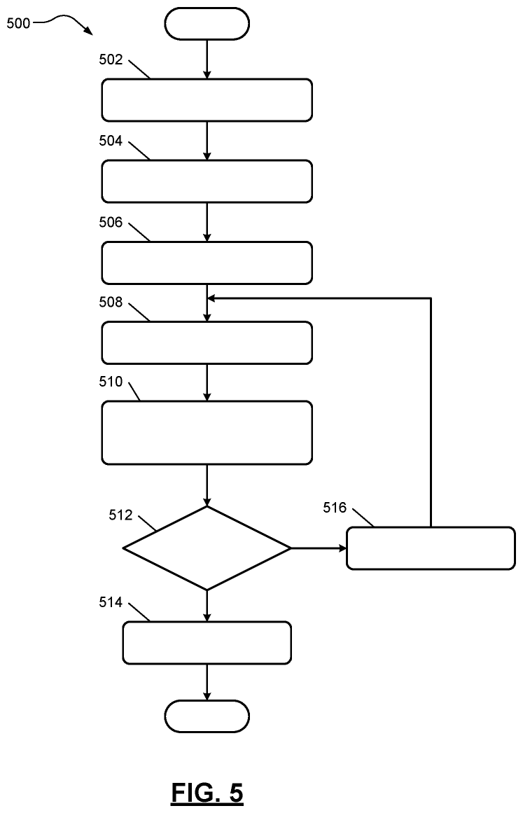

FIG. 5 illustrates an example process 500 for measuring capacitance values associated with a battery cell, such as the battery cell 100, 200 of FIGS. 1-2. While FIG. 5 is shown and described as including specific steps, it should be appreciated that the process 500 of FIG. 5 is one example variation that may be implemented and in other embodiments the process 500 and/or other example processes may include different steps, more or less steps, etc.

In the example of FIG. 5, the battery cell includes a battery cell enclosure (e.g., a battery cell pouch) having an inner layer made of an electrically conductive material and an outer layer made of an electrically insulative material, different sets of battery terminals arranged in the battery cell enclosure, and electrolyte located between the battery terminals. In such examples, one set of battery terminals is connected to cathodes or anodes of the battery cell and another set of battery terminals is connected to anodes or cathodes of the battery cell.

As shown in FIG. 5, the process 500 begins at 502 where a portion of the inner, electrically conductive layer of the battery cell enclosure is exposed. In various embodiments, the inner layer may be exposed by cutting the battery cell enclosure (e.g., cutting away the outer, electrically insulative layer). The process 500 then proceeds to 504.

At 504, a conductive portion (e.g., a metal foil) is placed on the exposed portion of the inner, electrically conductive layer. For example, and as explained above, the conductive portion may be wrapped around the exposed portion near an edge surface of the battery cell enclosure. In such examples, the conductive portion directly contacts the exposed portion of the inner layer (e.g., via an adhesive material or not), as explained above. The process 500 then proceeds to 506, 508.

At 506, a capacitance measurement module (e.g., the capacitance measurement module 304 of FIG. 3, the capacitance measurement module 444 of FIG. 4, etc.) is connected for measuring a capacitance value of the battery cell. Specifically, and as explained above, the capacitance measurement module is connected to the conductive portion and one of the sets of battery terminals in the battery cell enclosure to measure a capacitance value one or more times between the conductive portion and the battery terminals at 508. In various embodiments, the measured capacitance value(s) may be stored if desired. The process 500 then proceeds to 510.

At 510, the measured capacitance value(s) are compared to a defined capacitance threshold. For example, the measured capacitance value(s) may be directly compared to a capacitance threshold. In such examples, the capacitance threshold may be an initial or baseline capacitance value of the battery cell when the battery cell and the components therein (e.g., electrolyte) are satisfactory. In other examples, one or more parameters (e.g., a rate of change in the capacitance, etc.) associated with the battery cell may be calculated or otherwise determined based on the measured capacitance values and then compared to a threshold (e.g., based on an initial or baseline capacitance value of the battery cell). Regardless, changes in the measured capacitance values for the battery cell may be monitored and used to detect or predict battery cell aging, electrolyte consumption at the battery cell level, and/or other wear-related operating conditions of the battery cell. The capacitance values may also be used (with or without other battery cell parameters) to detect or predict thermal runaway of the battery cell and/or other battery operating conditions. Because the measured capacitance values are highly dependent upon the dielectric properties of the electrolyte, the battery system can be used to detect small changes in the molecular and physical structures of the battery cells. The process 500 then proceeds to 512.

At 512, a controller (e.g., in the capacitance measurement module, in the battery management system 440 of FIG. 4, etc.) determines whether the measured capacitance value (or parameter thereof) is greater than or equal to the threshold. In various embodiments, the threshold may depend on one or more factors, such as a frequency being monitored and/or a particular property being monitored (e.g., an electrolyte filling, an electrolyte dry out, a battery temperature, a pouch pin hole, etc.). If yes, the process 500 proceeds to 516 where no action is taken and then returns to 508, as shown in FIG. 5. However, if the measured capacitance value (or parameter thereof) is less than the threshold at 512, the process 500 proceeds to 514 where a correction action is taken. For example, the correction action may include a user notification to inspect the battery cell, replace the entire battery cell, replace a portion (e.g., electrolyte) of the entire battery cell, adjust an operating parameter of a battery system including the battery cell (e.g., battery cell balancing, charging levels and/or rate, discharging levels and/or rate, etc.), etc. The process 500 may then end as shown in FIG. 5.

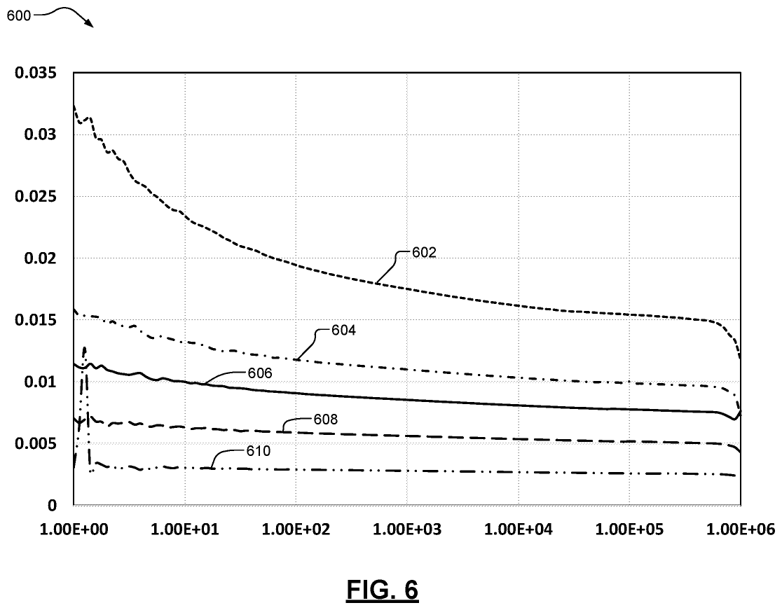

Referring now to FIG. 6, a graph 600 is depicted of measured capacitance values (Y-axis) for different connection arrangements over frequency (X-axis). Specifically, in the graph 600, the line 602 represents the measured capacitance values (micro farad (μF)) of a battery cell with a battery cell pouch having a conductive portion directly connected to an electrically conductive layer of the battery cell pouch, as explained herein. The lines 604, 606, 608, 610 represent the measured capacitance values (μF) of battery cells being capacitively coupled to external conductive plates as in conventional systems. Specifically, in the example of FIG. 6, the external conductive plates employed for the measured capacitance values associated with the lines 604, 606, 608, 610 are a 387 cm² plate, a 194 cm² plate, a 97 cm² plate, and a 39 cm² plate, respectively.

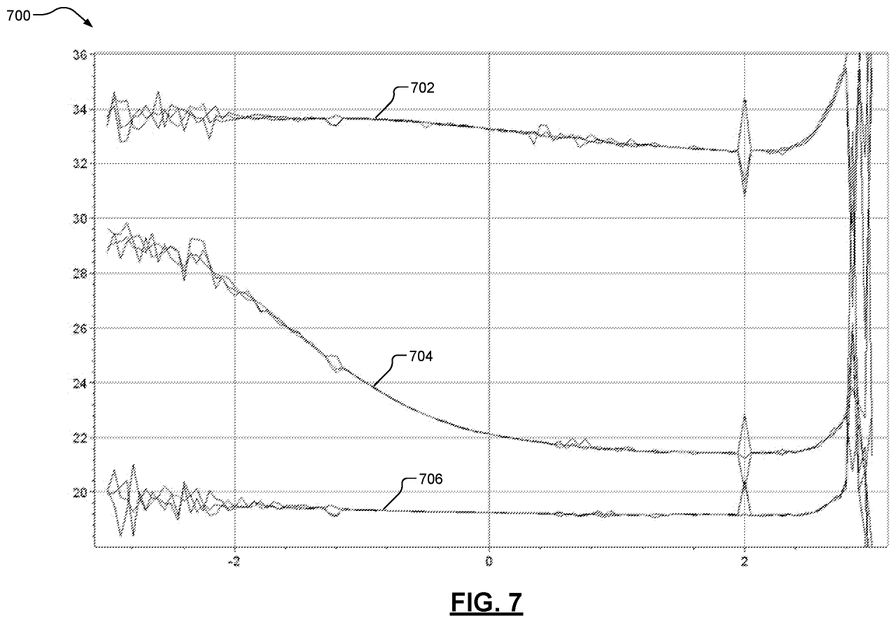

In various embodiments, measured capacitance values of one of the battery cells herein can be used for battery quality control, pin hole detection, battery state of health monitoring and early detection of thermal runaway. For example, FIGS. 7-10 depict graphs 700, 800, 900, 1000 of measured capacitance values (Y-axis) as a function of different battery parameters over frequency (X-axis).

In FIG. 7, the graph 700 generally includes lines 702, 704 showing capacitive battery measurements (nano farad (nF)) for two different electrolyte fillings and a line 706 showing capacitive battery measurements (nF) for an electrolyte dry out condition. As shown, the capacitive battery measurements may be monitored over frequency to detect if and/or predict when an electrolyte level in the battery cell is low.

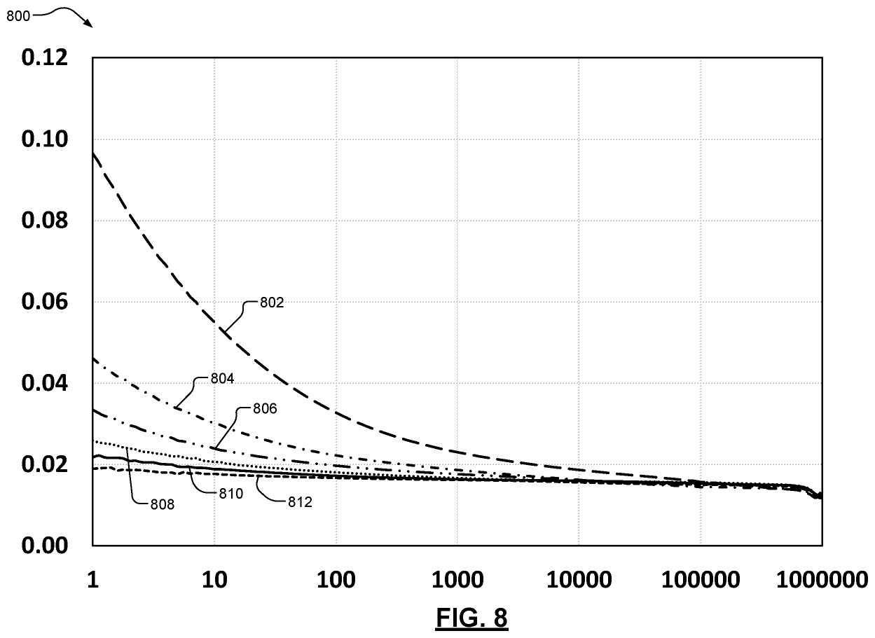

The graph 800 of FIG. 8 includes lines 802, 804, 806, 808, 810, 812 showing capacitive battery measurements (μF) at different battery temperatures over frequency. Specifically, the line 802 (large dash line) is at a temperature of 75 degrees Celsius, the line 804 (dash-dot-dash line) is at a temperature of 50 degrees Celsius, the line 806 (dash-dot-dot-dash line) is at a temperature of 25 degrees Celsius, the line 808 (dotted line) is at a temperature of 0 degrees Celsius, the line 810 (solid line) is at a temperature of −25 degrees Celsius, and the line 812 (small dash line) is at a temperature of −50 degrees Celsius.

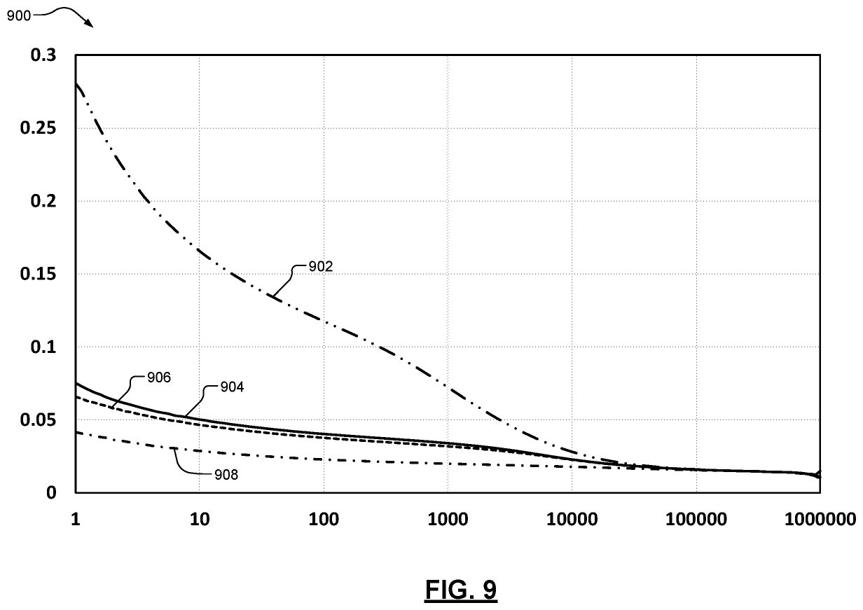

The graph 900 of FIG. 9 includes lines 902, 904, 906, 908 for showing capacitive battery measurements (μF) of battery cells with or without pouch pin holes at different frequencies. For example, the line 902 (dash-dot-dot-dash line) is a baseline of capacitive battery measurements in which the battery cell has no pouch pin holes, the line 904 (solid line) is capacitive battery measurements in which the battery cell has a pouch pin hole at about 5-minutes of testing, the line 906 (dash line) is capacitive battery measurements in which the battery cell has a pouch pin hole at about 15-minutes of testing, and the line 908 (dash-dot-dash line) is capacitive battery measurements in which the battery cell has a pouch pin hole at about 45-minutes of testing.

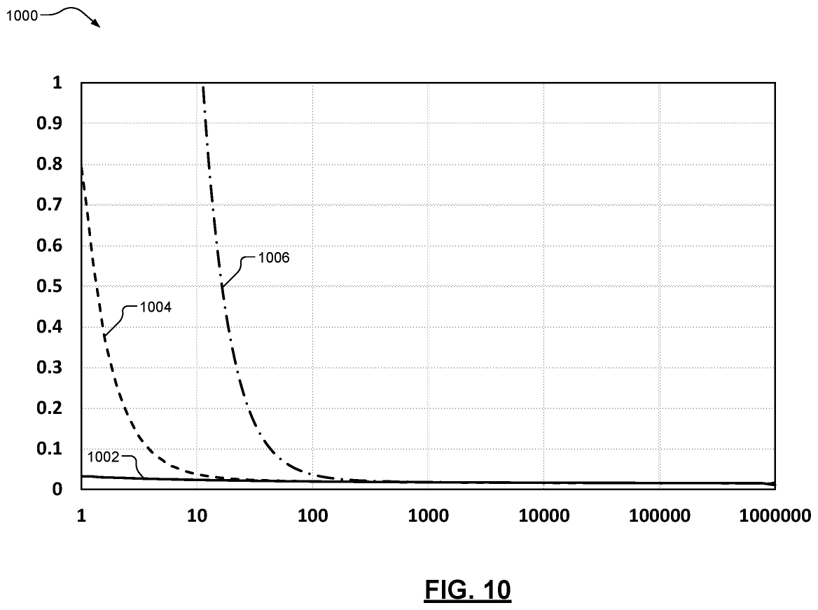

The graph 1000 of FIG. 10 includes lines 1002, 1004, 1006 for showing capacitive battery measurements (μF) of battery cells with different resistive values coupled across the cells to measure isolation. For example, the line 1002 (solid line) is capacitive battery measurements of an open circuit, the line 1004 (dash line) is capacitive battery measurements with a 100 k-ohm resistance coupled across the battery pouch cell, and the line 1006 (dash-dot-dash line) is capacitive battery measurements with a 1 M-ohm resistance coupled across the battery pouch cell.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” or the term “controller” may be replaced with the term “circuit.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

The term code, as used above, may include software, firmware, and/or microcode, and may refer to programs, routines, functions, classes, data structures, and/or objects. The term shared processor circuit encompasses a single processor circuit that executes some or all code from multiple modules. The term group processor circuit encompasses a processor circuit that, in combination with additional processor circuits, executes some or all code from one or more modules. References to multiple processor circuits encompass multiple processor circuits on discrete dies, multiple processor circuits on a single die, multiple cores of a single processor circuit, multiple threads of a single processor circuit, or a combination of the above. The term shared memory circuit encompasses a single memory circuit that stores some or all code from multiple modules. The term group memory circuit encompasses a memory circuit that, in combination with additional memories, stores some or all code from one or more modules.

The term memory circuit is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. The functional blocks, flowchart components, and other elements described above serve as software specifications, which can be translated into the computer programs by the routine work of a skilled technician or programmer.

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation) (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Swift, Haskell, Go, SQL, R, Lisp, Java®, Fortran, Perl, Pascal, Curl, OCaml, JavaScript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

1-16. (canceled)

17. A battery cell comprising:
a battery cell enclosure including an inner layer made of an electrically conductive material and an outer layer made of an electrically insulative material, wherein a portion of the inner layer is exposed;
first battery terminals arranged in the battery cell enclosure;
second battery terminals arranged in the battery cell enclosure;
electrolyte located between the first battery terminals and the second battery terminals; and
a conductive portion arranged adjacent to the outer layer and directly connected to the exposed portion of the inner layer.

18. The battery cell of claim 17, wherein the conductive portion is directly connected to the exposed portion of the inner layer via an adhesive material.

19. The battery cell of claim 18, wherein the adhesive material is a pressure sensitive adhesive.

20. The battery cell of claim 18, wherein the adhesive material is a conductive paint.

21. The battery cell of claim 17, wherein the conductive portion is directly connected to the exposed portion of the inner layer via at least one metallic plate clamped to the conductive portion.

22. The battery cell of claim 17, wherein the conductive portion includes a metal foil layer.

23. The battery cell of claim 17, wherein the conductive portion is made of copper or aluminum.

24. The battery cell of claim 17, wherein the electrically insulative material of the outer layer is a polymer material.

25. The battery cell of claim 17, wherein the exposed portion of the inner layer is an edge portion of the battery cell enclosure.

26. The battery cell of claim 17, wherein the battery cell comprises a pouch-type battery cell and the battery cell enclosure comprises a battery pouch.

27. The battery cell of claim 17, wherein:
the battery cell enclosure includes an interior layer made of an electrically insulative material; and
the inner layer includes a metal foil layer laminated between the interior layer and the outer layer.

28. The battery cell of claim 27, wherein the electrically insulative material of the interior layer is a polymer material.

29. A battery system comprising:
at least one pouch-type battery cell including:
a battery pouch having an inner layer made of an electrically conductive material and an outer layer made of an electrically insulative material, wherein a portion of the inner layer is exposed;
first battery terminals arranged in the battery pouch;
second battery terminals arranged in the battery pouch;
electrolyte located between the first battery terminals and the second battery terminals; and
a conductive portion arranged adjacent to the outer layer and directly connected to the exposed portion of the inner layer; and
a capacitance measurement module configured to measure capacitance values between the conductive portion of the at least one pouch-type battery cell and at least one of the first battery terminals and the second battery terminals of the at least one pouch-type battery cell.

30. The battery system of claim 29, wherein the conductive portion is directly connected to the exposed portion of the inner layer via an adhesive material.

31. The battery system of claim 29, wherein the conductive portion is directly connected to the exposed portion of the inner layer via at least one metallic plate clamped to the conductive portion.

32. The battery system of claim 29, wherein:
the conductive portion includes a metal foil layer; and
the electrically insulative material of the outer layer is a polymer material.

33. The battery system of claim 29, wherein the exposed portion of the inner layer is an edge portion of the battery pouch.

34. The battery system of claim 29, wherein:
the battery pouch includes an interior layer made of an electrically insulative material; and
the inner layer includes a metal foil layer laminated between the interior layer and the outer layer.

35. The battery system of claim 34, wherein the electrically insulative material of the interior layer is a polymer material.

36. A method for measuring capacitance values associated with a battery cell, the battery cell including a battery cell enclosure having an inner layer made of an electrically conductive material and an outer layer made of an electrically insulative material, first battery terminals arranged in the battery cell enclosure, second battery terminals arranged in the battery cell enclosure, and electrolyte located between the first battery terminals and the second battery terminals, the method comprising:
exposing a portion of the inner layer of the battery cell enclosure;
directly connecting a conductive portion to the exposed portion of the inner layer; and
connecting a capacitance measurement module to the conductive portion and the at least one of the first battery terminals and the second battery terminals of the battery cell to measure capacitance values between the conductive portion and the at least one of the first battery terminals and the second battery terminals.
